(19) United States
(12) Patent Application Publication
(10) Pub. No.: US 2026/0094631 A1
(43) Pub. Date: Apr. 2, 2026

(54) Computing-in-Memory Macro with Memory Bypass Mechanism

(71) Applicant: MEDIATEK INC., Hsinchu City (TW)

(72) Inventors: Chieh-Fang Teng, Hsinchu City (TW); En-Jui Chang, Hsinchu City (TW); Hsien-Peng Wang, Hsinchu City (TW); Jen-Wei Liang, Hsinchu City (TW)

(73) Assignee: MEDIATEK INC., Hsinchu City (TW)

(21) Appl. No.: 18/900,917

(22) Filed: Sep. 30, 2024

(51) Int. Cl. G11C 7/10

(52) U.S. Cl. CPC G11C 7/1012; G11C 7/1048; G11C 7/1096

(57) ABSTRACT

A computing-in-memory macro includes a memory cell, a multiplexer, and a compute cell. The memory cell is used to store weights of the computing-in-memory macro. The multiplexer is coupled to the memory cell and used to select a weight from the memory cell or a weight from an external path to output as an output weight. The compute cell is coupled to the multiplexer and used to generate an output of the computing-in-memory macro according to the output weight from the multiplexer and an activation.

### BACKGROUND

In response to the huge demand for information analysis brought by emerging technologies such as artificial intelligence, the Internet of Things, 5G, and vehicles, governments and internationally renowned manufacturers have actively invested a large amount of resources in recent years to accelerate development while improving computing speed and reducing energy consumption.

Data is the most important resource in today's digital economy. According to estimates, due to the popularity of handheld devices and the development of the Internet of Things (IoT), more than 2.5 quintillion bytes of data are generated every day, and the rate of data generation is still climbing.

Such a huge amount of data also means that a lot of computing resources are required to process it. Especially when computers currently based on the von Neumann architecture perform calculations, the data must be transferred between the computing unit (CPU or GPU) and the memory. This not only limits the overall efficiency and computing time, but also causes a large amount of energy consumption. This is because repeated data transmission limits performance improvement, resulting in the so-called memory wall.

Entering the era of integrating big data and artificial intelligence (AI), memory-centric chips, which allow memory to more closely integrate computing resources, have received considerable attention in recent years in order to overcome the limitations of the memory wall and improve computing performance.

The so-called memory-centric chip mainly refers to near-memory computing and computing-in-memory (CIM) (in-memory computing). These two technologies integrate memory and computing. Near-memory computing uses advanced packaging technology to integrate computing chips and memory chips using die-level integration, or integrate computing circuits and memory circuits in a monolithic manufacturing process. The goal of vertical device-level integration is to bring the data computing unit and the memory storage unit closer to reduce the transmission distance.

Computing-in-memory overcomes Von Neumann architecture limitations. As for computing-in-memory, it directly uses memory to process artificial neural networks in deep learning, including Deep Neural Network (DNN) and Convolutional Neural Network (CNN). For many neural network computing tasks, there is no need to repeatedly transfer data between the computing unit and the memory, which can overcome the limitations of the Von Neumann architecture and achieve significant improvements in computing performance.

For convolutional neural network (CNN), some weights can be reused in computing-in-memory. However, for deep neural network (DNN), each weight will only be used once. Therefore, a computing-in-memory macro with memory bypass mechanism is desired to support operations (whose weight cannot be reused) without internal memory access, so as to save energy.

### SUMMARY

An embodiment provides a computing-in-memory macro including a memory cell, a multiplexer, and a compute cell. The memory cell is used to store weights of the computing-in-memory macro. The multiplexer is coupled to the memory cell and used to select a weight from the memory cell or a weight from an external path to output as an output weight. The compute cell is coupled to the multiplexer and used to generate an output of the computing-in-memory macro according to the output weight from the multiplexer and an activation.

These and other objectives of the present disclosure will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a computing-in-memory (CIM) macro according to an embodiment of the present disclosure.

FIG. 2 is a circuit diagram of a CIM macro according to an embodiment of the present disclosure.

FIG. 3 is a circuit diagram of a CIM macro according to another embodiment of the present disclosure.

### DETAILED DESCRIPTION

Von Neumann architecture, also known as Von Neumann model or Princeton architecture, is a conceptual computer architecture that combines program instruction memory and data memory. This term describes a computing device that implements a universal Turing machine and a sequential architecture reference model (referential model) relative to parallel computing. This architecture vaguely guides the concept of separating storage devices from central processing units, so computers designed according to this architecture are also called stored-program computers.

The earliest computing machines contain only fixed-purpose programs. Some modern computers still maintain this design, usually for simplicity or educational purposes. For example, a calculator only has fixed mathematical calculation programs. It cannot be used as word processing software or for playing games. If a user wants to change the program of this machine, the user must change the wiring, change the structure or even redesign the machine. the earliest computers were not as programmable as they were designed to be. The so-called “rewriting the program” at that time most likely refers to the steps of designing the program with pen and paper, then working out the project details, and then changing the circuit wiring or structure of the machine.

The concept of stored-program computers changed all these things. By creating an instruction set architecture and converting so-called operations into the execution details of a sequence of program instructions, the machine is made more flexible. By treating instructions as a special type of static data, a stored-program computer can easily change its program and change the contents of its operations under program control. Von Neumann architecture and stored-program computers are interchangeable terms, and their usage will be described below. The Harvard architecture is a design concept that stores program data and ordinary data separately, but it does not completely break through the von Neumann architecture.

The concept of stored procedures also allows the program to self-modify the calculation content of the program when it is executed. One of the design motivations for this concept is to allow the program to add content or change the memory location of program instructions by itself, because early designs required manual modification by the user. But as index registers and indirect location access have become necessary mechanisms in the hardware architecture, this feature is not as important as it used to be. The feature of program self-modification has also been abandoned by modern programming because it makes understanding and debugging difficult, and the pipeline and cache mechanism of modern CPUs will make this function less efficient.

On the whole, the concept of treating instructions as data enables the realization of assembly languages, compilers and other automatic programming tools; these “automatic programming programs” can be used to write programs in a way that is easier for humans to understand; from a local perspective it seems that for machines that emphasize input/output (I/O), such as Bitblt, if the user wants to modify the graphics on the screen, it used to be thought that it was impossible without customized hardware. But later it was shown that these functions can be effectively achieved through “execution compilation” technology.

Separating the central processing unit (CPU) from the memory is not perfect and can lead to the so-called Von Neumann bottleneck: the flow rate (data transfer rate) between the CPU and memory is quite small compared to the memory capacity. In modern computers, the data flow is very small compared to the CPU's work efficiency. In some cases (when the CPU needs to execute some simple instructions on huge data), the data flow becomes a very serious limitation on the overall efficiency. The CPU will be idle while data is being input or output to memory. Since the CPU speed is much greater than the memory read and write rate, the bottleneck problem becomes more and more serious. Therefore, computing-in-memory technology is desired.

In applications of artificial intelligence (AI), memory usage is an essential issue. Huge amount of weights is applied in AI applications especially in deep neural network (DNN) and convolutional neural network (CNN). For CNN, some weights can be reused in computing-in-memory. However, for DNN, each weight will only be used once. Therefore, a computing-in-memory macro with memory bypass mechanism is desired to support operations (whose weight cannot be reused) without internal memory access, so as to save energy.

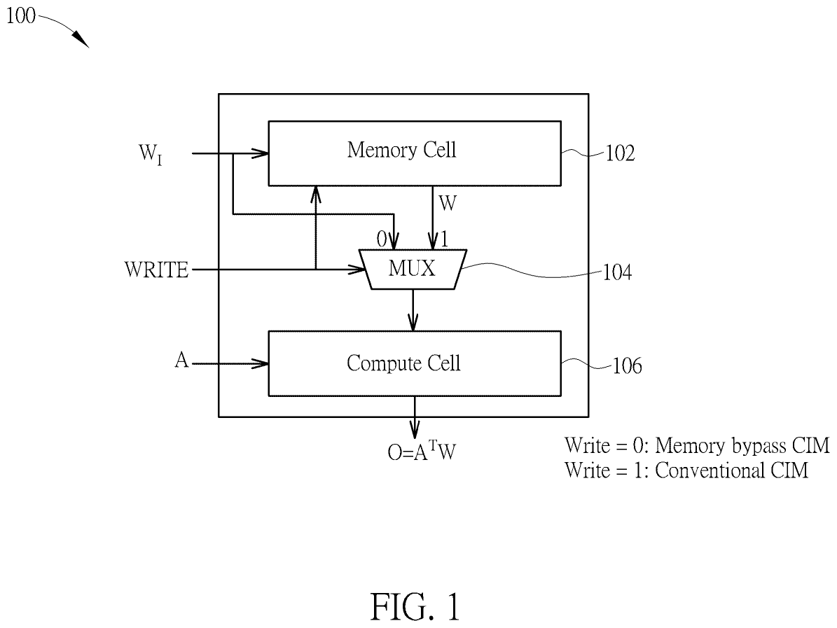

FIG. 1 is a computing-in-memory (CIM) macro 100 according to an embodiment of the present disclosure. The CIM macro 100 includes a memory cell 102, a multiplexer (MUX) 104, and a compute cell 106. The memory cell 102 is used to store weights of the CIM macro 100, and the weights can be used to calculate a result in conventional computing-in-memory. The multiplexer 104 is coupled to the memory cell 102 and used to select a weight W from the memory cell 102 or a weight W from an external path to output as an output weight. The multiplexer 104 selects the weight W from the memory cell 102 or the weight W_{I} from the external path to output the output weight according to a WRITE bit. As shown in FIG. 1, in one embodiment, when the WRITE bit is 0, the multiplexer 104 selects the weight W_{I} from the external path. When the WRITE bit is 1, the multiplexer 104 selects the weight W from the memory cell 102. Then, the multiplexer 104 outputs the output weight to the compute cell 106. The compute cell 106 is coupled to the multiplexer 104 and used to generate an output of the computing-in-memory macro 100 according to the output weight from the multiplexer 104 and an activation A. The output of the computing-in-memory macro 100 can be calculated as:

$$O = {A}^{T} W or {A}^{T} {W}_{I}$$

Wherein O the output of the computing-in-memory macro 100, A^{T} is a transpose of the activation A, W is the weight from the memory cell 102, and W_{I} is the weight from the external path.

By adding a multiplexer 104 to a conventional computing-in-memory macro, the CIM macro 100 with memory bypass mechanism can select the weight W from the memory cell 102 or the weight W_{I} from the external path, providing a flexible solution. In an example, when the CIM macro 100 is used in DNN application, the WRITE bit can be configured as 0 to bypass the memory cell 102 and read the weight W_{I} from the external path. When the CIM macro 100 is used in CNN application, the WRITE bit can be configured as 1 to provide conventional CIM and read the weight W from the memory cell 102. The value “0” and “1” here are examples, in other embodiments, other value may be used, for example, a first value (a numeric value or a logical value) of the WRITE bit is used to indicate a bypass the memory cell 102 and read the weight W_{I} from the external path, and a second value (a numeric value or a logical value) of the WRITE bit is used to indicate to provide conventional CIM and read the weight W from the memory cell 102. Therefore, the CIM macro 100 with memory bypass mechanism is provided to skip redundant internal memory access for energy saving.

In an embodiment, the memory cell 102 can be a static random-access memory (SRAM) cell, a dynamic random-access memory (DRAM) cell, a flash memory cell, a resistive random-access memory (RRAM) cell, a phase-change memory (PCM) cell, a spin-transfer torque magnetic random-access memory (STT-MRAM) cell, or any other types of memory cell.

In an embodiment, the compute cell 106 can be any logic gate (e.g., AND gate, NOR gate, OR gate, etc.) or any combinations of logic gates depending on the desired functions in compute cell. For example, the compute cell 106 can be an AND gate, a NOR gate, a OR gate, or a matrix-vector multiplication (MVM) which consists of more than one logic gate.

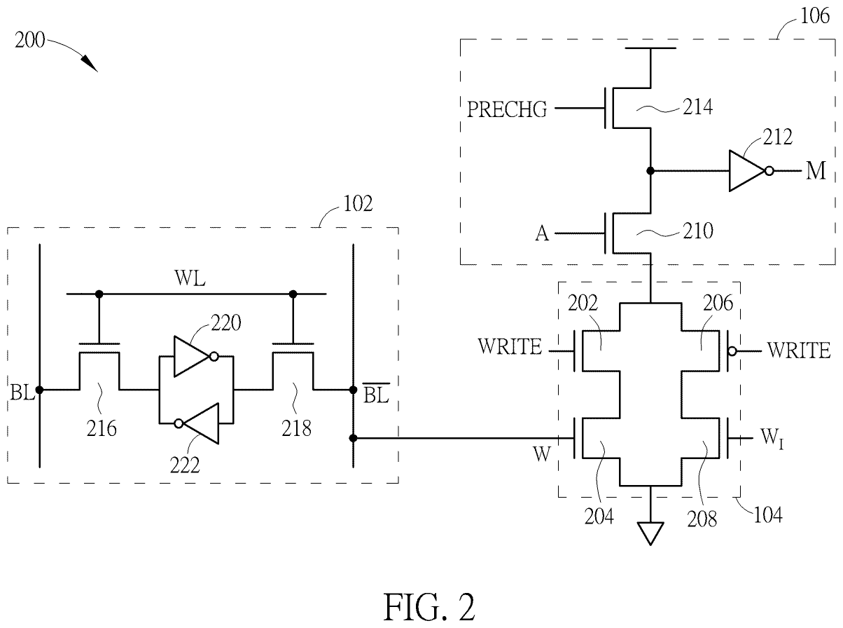

FIG. 2 is a circuit diagram of a CIM macro 200 according to an embodiment of the present disclosure. The CIM macro 200 includes a memory cell 102, a multiplexer 104, and a compute cell 106. The multiplexer 104 includes a first N-type metal oxide semiconductor (NMOS) 202, a P-type metal oxide semiconductor (PMOS) 206, a second NMOS 204, and a third NMOS 208.

The first NMOS 202 includes a drain, a source, and a gate. The drain of the first NMOS 202 is coupled to an output end of the multiplexer 104. The gate of the first NMOS 202 is used to receive a WRITE bit. The PMOS 206 includes a source, a drain, and a gate. The source of the PMOS 206 is coupled to the output end of multiplexer 104. The gate of the PMOS 206 is used to receive the WRITE bit. The second NMOS 204 includes a drain, a source, and a gate. The drain of the second NMOS 204 is coupled to the source of the first NMOS 202. The source of the second NMOS 204 is coupled to a ground. The gate of the second NMOS 204 is used to receive a weight W from the memory cell 102. The third NMOS 208 includes a drain, a source, and a gate. The drain of the third NMOS 208 is coupled to the drain of the PMOS 206. The source of the third NMOS 208 is coupled to the ground. The gate of the third NMOS 208 is used to receive the weight W_{I} from the external path.

The compute cell 106 includes a fourth NMOS 210, a first inverter 212, and a fifth NMOS 214. The fourth NMOS 210 includes a drain, a source, and a gate. The source of the fourth NMOS 210 is coupled to the output end of the multiplexer 104. The gate of the fourth NMOS 210 is used to receive an activation bit A. The first inverter 212 includes an input end and an output end. The input end of the first inverter 212 is coupled to the drain of the fourth NMOS 210. The output end of the first inverter 212 is used to output the output M of the computing-in-memory macro 200. The fifth NMOS 214 includes a drain, a source, and a gate. The drain of the fifth NMOS 214 is coupled to a power supply. The source of the fifth NMOS 214 is coupled to the drain of the fourth NMOS 210. The gate is used to receive a precharge signal, the precharge signal in FIG. 2 is configured to turn on the fifth NMOS 214 to input the power supply to the first inverter 212 when the fourth NMOS 210 is turned off or the output end of the multiplexer 104 is low; and turn off the fifth NMOS 214 to allow the ground to be input into the first inverter 212 when the fourth NMOS 210 is turned on and the output end of the multiplexer 104 is high.

The memory cell 102 (which is a SRAM) includes a sixth NMOS 216, a seventh NMOS 218, a second inverter 220, and a third inverter 222. The sixth NMOS 216 includes a drain, a source, and a gate. The source of the sixth NMOS 216 is coupled to a bit line BL. The gate of the sixth NMOS 216 is coupled to a word line WL. The seventh NMOS 218 includes a drain, a source, and a gate. The drain of the seventh NMOS 218 is coupled to a bit line bar B̅L̅ and the gate of the second NMOS 204. The gate of the seventh NMOS 218 is coupled to the word line WL. The second inverter 220 includes an input end and an output end. The input end of the second inverter 220 is coupled to the drain of the sixth NMOS 216. The output end of the second inverter 220 is coupled to the source of the seventh NMOS 218. The third inverter 222 includes an input end and an output end. The input end of the third inverter 222 is coupled to the source of the seventh NMOS 218. The output end of the third inverter 222 is coupled to the drain of the sixth NMOS 216.

The output M of the CIM macro 200 with memory bypass mechanism can be calculated as the following truth table:

TABLE 1
Truth table of the CIM macro 200 with memory bypass mechanism

| WRITE | A | W_{I} | W | M = (A & ((W & WRITE) \| (W_{I} & ~WRITE))) |
|---|---|---|---|---|
| 0 | 0 | 0 | x | 0 |
| 0 | 0 | 1 | x | 0 |
| 0 | 1 | 0 | x | 0 |
| 0 | 1 | 1 | x | 1 |
| 1 | 0 | x | 0 | 0 |
| 1 | 0 | x | 1 | 0 |
| 1 | 1 | x | 0 | 0 |
| 1 | 1 | x | 1 | 1 |

In TABLE 1, when the WRITE bit is 0, the output M is equal to (A&W_{I}). When the WRITE bit is 1, the output M is equal to (A&W). Therefore, the output M is generated from the weight W_{I} from the external path as WRITE bit is 0, and is generated from the weight W from the memory cell 102 as WRITE bit is 1. It should be noticed that the values in TABLE 1 are just examples, these values are not intended to limit the scope of the present disclosure, thus, these values can be change to any other numeric values or logical values according to design requirements. By configuring the WRITE bit, the output M of the CIM macro 200 can flexibly change. In this embodiment, the connection of the compute cell 106 and the multiplexer 104 forms an AND operation between the activation A and the output weight of the multiplexer 104. However, the invention is not limited to the AND operation. It can also be OR, NOR, or other operations.

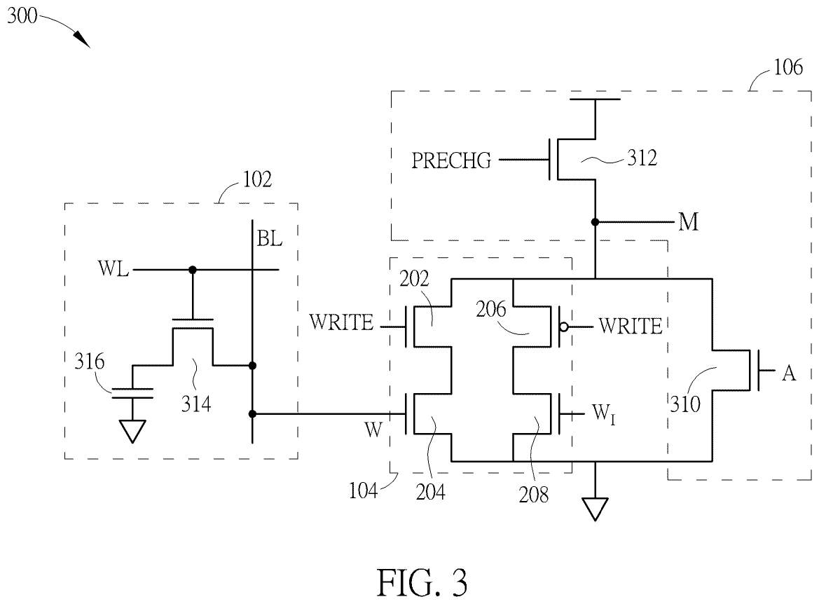

FIG. 3 is a circuit diagram of a CIM macro 300 according to another embodiment of the present disclosure. The CIM macro 300 includes a memory cell 102, a multiplexer 104, and a compute cell 106. The multiplexer 104 includes a first NMOS 202, a PMOS 206, a second NMOS 204, and a third NMOS 208. The multiplexer 104 works in the same way as in FIG. 2 and thus is not elaborated herein.

The compute cell 106 includes a fourth NMOS 310, and a fifth NMOS 312. The fourth NMOS 310 includes a drain, a source, and a gate. The drain of the fourth NMOS 310 is coupled to the output end of the multiplexer 104, and used to output the output M of the CIM macro 300. The source of the fourth NMOS 310 is coupled to the ground. The gate of the fourth NMOS 310 is used to receive an activation bit A. The fifth NMOS 312 includes a drain, a source, and a gate. The drain of the fifth NMOS 312 is coupled to a power supply. The source of the fifth NMOS 312 is coupled to the drain of the fourth NMOS 310. The gate of the fifth NMOS 312 is used to receive a precharge signal, the precharge signal in FIG. 3 is configured to turn on the fifth NMOS 312 to output a logic high(1) as the output M when the fourth NMOS 310 is turned off and the output end of the multiplexer 104 is low; and turn off the fifth NMOS 312 to output a logic low(0) as the output M when the fourth NMOS 210 is turned on or the output end of the multiplexer 104 is high.

The memory cell 102 (which is a DRAM) includes a sixth NMOS 314 and a capacitor 316. The sixth NMOS 314 includes a drain, a source and a gate. The drain of the sixth NMOS 314 is coupled to a bit line BL and the gate of the second NMOS 204. The gate of the sixth NMOS 314 is coupled to a word line WL. The capacitor 316 includes a first end and a second end. The first end of the capacitor 316 is coupled to the source of the sixth NMOS 314. The second end of the capacitor 316 is coupled to the ground.

TABLE 2
Truth table of the CIM macro 300 with memory bypass mechanism

| Write | A | W_{I} | W | M = A NOR ((W & Write) \| (W_{I} & ~Write)) |
|---|---|---|---|---|
| 0 | 0 | 0 | x | 1 |
| 0 | 0 | 1 | x | 0 |
| 0 | 1 | 0 | x | 0 |
| 0 | 1 | 1 | x | 0 |
| 1 | 0 | x | 0 | 1 |
| 1 | 0 | x | 1 | 0 |
| 1 | 1 | x | 0 | 0 |
| 1 | 1 | x | 1 | 0 |

In TABLE 2, when the WRITE bit is 0, the output M is equal to (A NOR W_{I}). When the WRITE bit is 1, the output M is equal to (A NOR W). Therefore, the output M is generated from the weight W_{I} from the external path as WRITE bit is 0, and is generated from the weight W from the memory cell 102 as WRITE bit is 1. It should be noticed that the values in TABLE 2 are just examples, these values are not intended to limit the scope of the present disclosure, thus, these values can be change to any other numeric values or logical values according to design requirements. By configuring the WRITE bit, the output M of the CIM macro 300 can flexibly change. In this embodiment, the connection of the compute cell 106 and the multiplexer 104 forms a NOR operation between the activation A and the output weight of the multiplexer 104. However, the invention is not limited to the NOR operation. It can also be OR, AND, or other operations.

In an embodiment, the memory cell 102 in FIG. 2 can be connected to the multiplexer 104 and the compute cell 106 in FIG. 3. The memory cell 102 in FIG. 3 can be connected to the multiplexer 104 and the compute cell 106 in FIG. 2. Besides, the memory cell 102 in this disclosure can be any logic gate (e.g., AND gate, NOR gate, OR gate, etc.) or any combinations of logic gates depending on the desired functions in compute cell. For example, the compute cell 106 can be an AND gate, a NOR gate, a OR gate, or a matrix-vector multiplication (MVM) which consists of more than one logic gate, or any other types of memory cell.

In conclusion, the computing-in-memory macro 200, 300 with memory bypass mechanism skips redundant internal memory access for energy saving. The multiplexer 104 is added between the memory cell 102 and compute cell 106 to select the weight W from the memory cell 102 or the weight W_{I} from the external path according to the WRITE bit. Therefore, the CIM macro 200, 300 may choose desired path of weight by configuration to save energy and computing time.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A computing-in-memory macro, comprising:
a memory cell, configured to store weights of the computing-in-memory macro;
a multiplexer, coupled to the memory cell, and configured to select a weight from the memory cell or a weight from an external path to output as an output weight; and
a compute cell, coupled to the multiplexer, and configured to generate an output of the computing-in-memory macro according to the output weight from the multiplexer and an activation.

2. The computing-in-memory macro of claim 1, wherein the multiplexer selects the weight from the memory cell or the weight from the external path according to a WRITE bit.

3. The computing-in-memory macro of claim 2, wherein when the WRITE bit is a first value, the multiplexer selects the weight from the memory cell to output as the output weight.

4. The computing-in-memory macro of claim 2, wherein when the WRITE bit is a second value, the multiplexer selects the weight from the external path to output as the output weight.

5. The computing-in-memory macro of claim 1, wherein the memory cell is a static random-access memory (SRAM) cell, a dynamic random-access memory (DRAM) cell, a flash memory cell, a resistive random-access memory (RRAM) cell, a phase-change memory (PCM) cell, or a spin-transfer torque magnetic random-access memory (STT-MRAM) cell.

6. The computing-in-memory macro of claim 1, wherein the memory cell is a charge-based memory cell or a resistance-based memory cell.

7. The computing-in-memory macro of claim 1, wherein the compute cell is an AND gate, a NOR gate, a OR gate, or a matrix-vector multiplication (MVM).

8. The computing-in-memory macro of claim 1, wherein the multiplexer comprises:
a first N-type metal-oxide-semiconductor (NMOS), comprising:
a drain, coupled to an output end of multiplexer;
a source; and
a gate, configured to receive a WRITE bit;
a P-type metal-oxide-semiconductor (PMOS), comprising:
a source, coupled to the output end of multiplexer;
a drain; and
a gate, configured to receive the WRITE bit;
a second NMOS, comprising:
a drain, coupled to the source of the first NMOS;
a source, coupled to a ground; and
a gate, configured to receive a weight from the memory cell; and
a third NMOS, comprising:
a drain, coupled to the drain of the first PMOS;
a source, coupled to the ground; and
a gate, configured to receive the weight from the external path.

9. The computing-in-memory macro of claim 8, wherein the compute cell comprises:
a fourth NMOS, comprising:
a drain;
a source, coupled to the output end of the multiplexer; and
a gate, configured to receive an activation bit; and
a first inverter, comprising:
an input end, coupled to the drain of the fourth NMOS; and
an output end, configured to output the output of the computing-in-memory macro.

10. The computing-in-memory macro of claim 9, wherein the compute cell further comprises a fifth NMOS comprising:
a drain coupled to a power supply;
a source, coupled to the drain of the fourth NMOS; and
a gate, configured to receive a precharge signal.

11. The computing-in-memory macro of claim 10, wherein the precharge signal is configured to turn on the fifth NMOS when the fourth NMOS is turned off or the output end of multiplexer is low, and turn off the fifth NMOS when the fourth NMOS is turned on and the output end of multiplexer is high.

12. The computing-in-memory macro of claim 9, wherein the memory cell comprises:
a sixth NMOS, comprising:
a drain;
a source, coupled to a bit line; and
a gate, coupled to a word line;
a seventh NMOS, comprising:
a drain, coupled to a bit line bar and the gate of the second NMOS;
a source; and
a gate, coupled to the word line;
a second inverter, comprising:
an input end, coupled to the drain of the sixth NMOS; and
an output end, coupled to the source of the seventh NMOS; and
a third inverter, comprising:
an input end, coupled to the source of the seventh NMOS; and
an output end, coupled to the drain of the sixth NMOS.

13. The computing-in-memory macro of claim 8, wherein the compute cell comprises:
a fourth NMOS, comprising:
a drain, coupled to the output end of the multiplexer, and configured to output the output of the computing-in-memory macro;
a source, coupled to the ground; and
a gate, configured to receive an activation bit.

14. The computing-in-memory macro of claim 13, wherein the compute cell further comprises a fifth NMOS comprising:
a drain coupled to a power supply;
a source, coupled to the drain of the fourth NMOS; and
a gate, configured to receive a precharge signal.

15. The computing-in-memory macro of claim 14, wherein the precharge is configured to turn on the fifth NMOS when the fourth NMOS is turned off and the output end of multiplexer is low, and turn off the fifth NMOS when the fourth NMOS is turned on or the output end of multiplexer is high.

16. The computing-in-memory macro of claim 8, wherein the memory cell comprises:
a sixth NMOS, comprising:
a drain, coupled to a bit line and the gate of the second NMOS;
a source; and
a gate, coupled to a word line; and
a capacitor, comprising:
a first end, coupled to the source of the sixth NMOS; and
a second end, coupled to the ground.
